(19) United States
(12) Patent Application Publication
(10) Pub. No.: US 2013/0206446 A1
(43) Pub. Date: Aug. 15, 2013

(54) Cord Organizer System

(71) Applicant: INGENETEK LLC, (US)

(72) Inventors: Trevor I. Briedé, Naples, FL (US); Margaret L. Lee, Naples, FL (US)

(73) Assignee: INGENETEK LLC, Naples, FL (US)

(21) Appl. No.: 13/732,933

(22) Filed: Jan. 2, 2013

Related U.S. Application Data
(60) Provisional application No. 61/598,981, filed on Feb. 15, 2012.

(51) Int. Cl. H05K 5/03

(52) U.S. Cl. CPC H05K 5/03
USPC 174/66

(57) ABSTRACT

A cord organizer system having a back plate, securable to a wall or adaptable to a track on an office desk having a centrally disposed opening for placement around a wall mounted electrical outlet, and a cover panel, releasably securable to the back plate for concealment of electrical cords. The back plate further includes at least one channel for organized positioning of electrical cords. The cover panel is constructed of a paintable material to allow for the cord organizer system to blend with a wall color and includes vents to allow for the dissipation of heat within the system occurring with the use of electrical cords. A closed top cover with a plurality of opening can be provided to allow for the pass through of electrical cords.

### PRIORITY CLAIM

In accordance with 37 C.F.R. 1.76, a claim of priority is included in an Application Data Sheet filed concurrently herewith. Accordingly, the present invention claims priority under 35 U.S.C. §119(e), 120, 121, and/or 365(c) to U.S. Provisional Application No. 61/598,981, entitled “CORD ORGANIZER”, filed Feb. 15, 2012. The contents of which the above referenced application is incorporated herein by reference.

### FIELD OF THE INVENTION

This invention relates generally to the field of organizers for electrical cords and, more particularly, to a wall mountable device for organized positioning and concealment of electrical cords.

### BACKGROUND OF THE INVENTION

Office workers are well aware that a conglomeration of electrical cords exists around most electrical receptacles. The multitude of wiring results from the use of desk lamps, cell phone chargers, radios, clocks, and other office items that must be inserted in electrical outlets in order to function. The use of desktop computers has heightened this problem as separate electrical cords are required for the monitor, CPU base, printer, modems, and other attachments. Other components typically found on a desktop such as a keyboard, mouse, external USB connections, telephone and so forth all combine to form a bundle of cords that is easily entangled. The mix not only results in an unsightly bundle of wires that can distract from what might otherwise be a well organized office, but creates a problem if one were seeking to relocate or remove a cord from just one piece of computer or office equipment.

Within an office environment, the bundle of wires may be concealed from view by placement of a desk in front of the receptacle that has electrical cords inserted therein. However, having the desk placed in front of the electrical receptacle can result in an unorganized bundle of electrical cords underneath the desk susceptible to being kicked, pulled, or tangled. Not only is the unorganized collaboration of cords unsightly and susceptible to wandering feet, but the entanglement of cords makes it difficult to clean around. It will simply collect dust and entrap anything that falls into the area. Paper articles entrapped within this area can create a fire hazard if the cords generate heat. Should a vacuum cleaner ingest one or more cords it can quickly strip insulation from the cord leaving an electrical shock hazard. Even simple movement of one or more wires can cause problems with the interconnections leading to employee downtime. Even in a home office, the bundling of wires results in a similar if not more complicated problem. In many instances the bundle of wires in a home setting is complicated with the addition of a television set, satellite receiver, and so forth. The cables in a home office setting not only present the same unsightly collection of wires that may be seen in a conventional office, but further creates a nuisance and possible safety hazard to small children and pets. Household pets can be particularly inquisitive and are known to chew on cables or even become entangled in the cords.

Most office and home desks include a modular tracking system that allows for easy installation of modular parts as well as accommodating for varying height considerations. Several manufacturers exist in the art, and each manufacturer has their own tracking width and spacing. The availability of a cord organizer adaptable to the various tracking systems associated with multiple desk manufacturers is lacking. Several do-it-yourself solutions exist for dealing with cords and cables. One solution is to hide the cords and wires under the flooring. It is easiest to accomplish this feat when replacing the flooring, otherwise bringing up a section of the existing flooring could cause considerable disruption within the room and, should one of the cords or wires need to be replaced, the flooring would have to be raised. A second solution is the use of zip ties. Zip ties can be used to hold the cords and wires in a bundle that can then be tacked to the underside of a desk or one of the desk legs. While zip ties keep cords and wires more organized, they do not hide them and when a need arises to reach and work with just one cord the ties have to be cut, the bundle disassembled, then later reassembled, and tied together.

Numerous types of organizers exist for cords and cables. U.S. Pat. No. 7,172,456 discloses an electric cable organizing device comprised of pair of brackets that are attached to an electric outlet strip. The brackets are spaced apart with an elastomer o-ring across each bracket to help secure cords and cables in position. However, the electrical cords are still visible and unsightly despite being organized and held in place.

U.S. Pat. No. 7,446,260 discloses a modular device for organizing cords. The device utilizes a rectangular box design having slotted side panels which are slanted and sized so that a plurality of modular cord bars may be inserted therein. Each modular cord bar is designed with a number of notches for winding and holding a cord in place at varying lengths and allowing the user to leave only the desired amount of cord loose. Although the modular device conceals and organizes electrical cords, the disadvantage associated therewith is that it is not adaptable to a desk tracking system and does not mount flush against an in-wall electrical receptacle, thereby still exposing at least one electrical cord.

U.S. Pat. No. 7,491,903 discloses a cable organizer including a cable spool that is mountable to an underside of a desk and so used to organize, store, and separate cables. The cable spool is formed from cup structures that are fitted or snapped together in a stacked array. Although the cable organizer is fashionable, the cords are still exposed between cup-shaped structures and susceptible to wandering feet.

Other prior art cord organizers include U.S. Pat. Nos. 7,078,617; 6,037,538; 5,971,508; 5,934,203; 5,934,201; 5,235,136; 5,231,562; and 4,255,610.

What is lacking in the art is a simplistic organizer that will organize, contain, and conceal the myriad of power cords typically associated with an electrical receptacle and which is mountable against a wall or adaptable to tracking system typically associated with modular desk furniture.

### SUMMARY OF THE INVENTION

The instant invention is a cord organizer comprising a back plate having a centrally disposed opening that allows the back plate to be placed around an electrical socket. The back plate is secured to the wall with screws, nails, or adhesive or, in an alternative embodiment, is adaptable to tracking found in modular desk furniture. The back plate includes a holder for a UPS/power strip and a plurality of channels for use in securing and maintaining electrical cords in an organized manner. On each side of the back plate an attachment fitting is used for releaseable securement of a cover panel. The cover panel is used to conceal the cords and the electrical socket once installed. The cover panel is defined by a front wall having side walls for securement to the back plate, a bottom wall and an open top. The cover panel may be of a paintable material allowing it to be painted to match the wall color.

Thus, an objective of the invention is to disclose a cord organizer system to organize and contain the myriad of power cords typically associated with the installation of a multitude of electrical devices in order to avoid interference with the feet and legs of the person working at the desk.

Yet another objective of the instant invention is to disclose a two piece cord organizer having a back plate mountable to the wall and a cover panel for concealing cords secured to the back plate.

Still another objective of the instant invention is to disclose a cord organizer system that conceals the electrical outlet and the unsightly tangle of cords that are connected thereto to create a cleaner and more appealing office environment. Additionally, the system provides a safeguard for electrical outlets by preventing unnecessary exposure to the electrical outlets and the interconnecting power cords.

Yet still another objective of the instant invention is to provide a cover panel that is paintable to conform to the interior color scheme of a particular office.

Still another objective of the instant invention is to reduce the potential electrical shock or fire hazard associated with exposure of un-organized cords by preventing contact with the cords once properly mounted and concealed.

Yet another objective of the instant invention is to provide a cord organizer system adaptable to tracks on modular desk furniture. Although various tracking systems exists for multiple manufacturers, the cord organizer will include hanger style attachments that can be placed intermittently to correspond to any number of various tracking spacing and width. The hanger attachment can be pre-fabricated to include a perforated cut-out portion on the back plate that, during user-installation, can be punched-out and bent to face backwards towards the wall, and therefore available to hang on tracking holes.

Another objective of the instant invention is to provide a cord organizer having slats or vents to help dissipate heat away from the organizer.

Still yet another objective of the instant invention is to provide a cord organizer having a shelf for placement of a powerstrip thereon. The use of a powerstrip permits a greater number of electrical cords to be introduced into the instant invention without cluttering the wall mounted electrical receptacle.

Other objectives and advantages of this invention will become apparent from the following description taken in conjunction with any accompanying drawings wherein are set forth, by way of illustration and example, certain embodiments of this invention. Any drawings contained herein constitute a part of this specification and include exemplary embodiments of the present invention and illustrate various objects and features thereof.

### BRIEF DESCRIPTION OF THE DRAWINGS

FIG. 1 is a front perspective view of the cord organizer system;

FIG. 2 is a rear perspective view of the cord organizer system;

FIG. 3 is a front perspective view of the back plate of the cord organizer system;

FIG. 4 is a front perspective view of the cover panel of the cord organizer system;

FIG. 5 is bottom perspective view of the cover panel of the cord organizer system;

FIG. 6 is a top perspective view of the top cover of the cord organizer system;

FIG. 7 is a front perspective view of the second embodiment of the cord organizer system;

FIG. 8 is a front perspective view of back plate and cover panel of the second embodiment of the cord organizer system;

FIG. 9 is front perspective view of the bottom portion back plate of the second embodiment of the cord organizer system;

FIG. 10 is front perspective view of the top portion back plate of the second embodiment of the cord organizer system;

FIG. 11 is front perspective view of the back plate of the second embodiment of the cord organizer system;

FIG. 12 is front perspective view of the lower portion cover panel of the second embodiment of the cord organizer system;

FIG. 13 is front perspective view of the upper portion cover panel of the second embodiment of the cord organizer system;

FIG. 14 is a rear perspective view of the second embodiment of the cord organizer system;

FIG. 15 is bottom perspective view of the second embodiment of the cord organizer system;

FIG. 16 is top perspective view of the top cover of the second embodiment of the cord organizer system;

FIG. 17 is front perspective and exploded view of the alternative fastener of the cord organizer system;

FIG. 18 is front illustrated view of the alternative fastener with a tracking system of the cord organizer system.

### DETAILED DESCRIPTION OF THE INVENTION

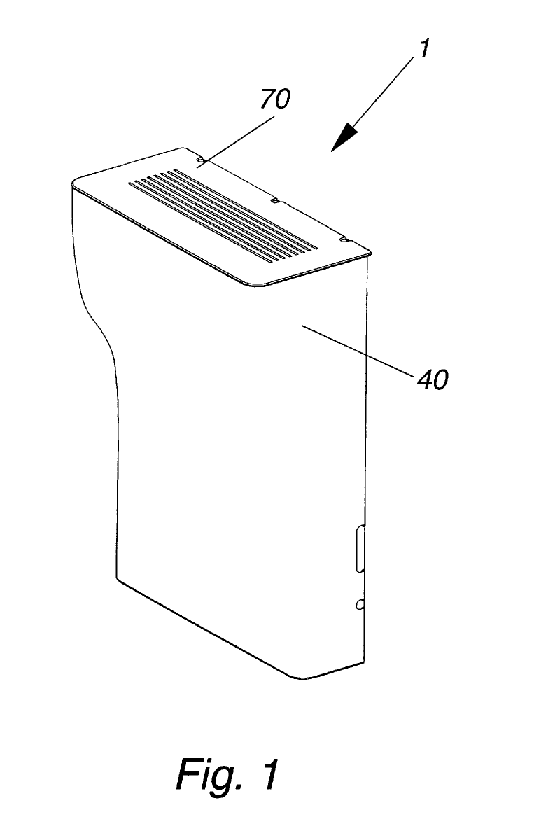

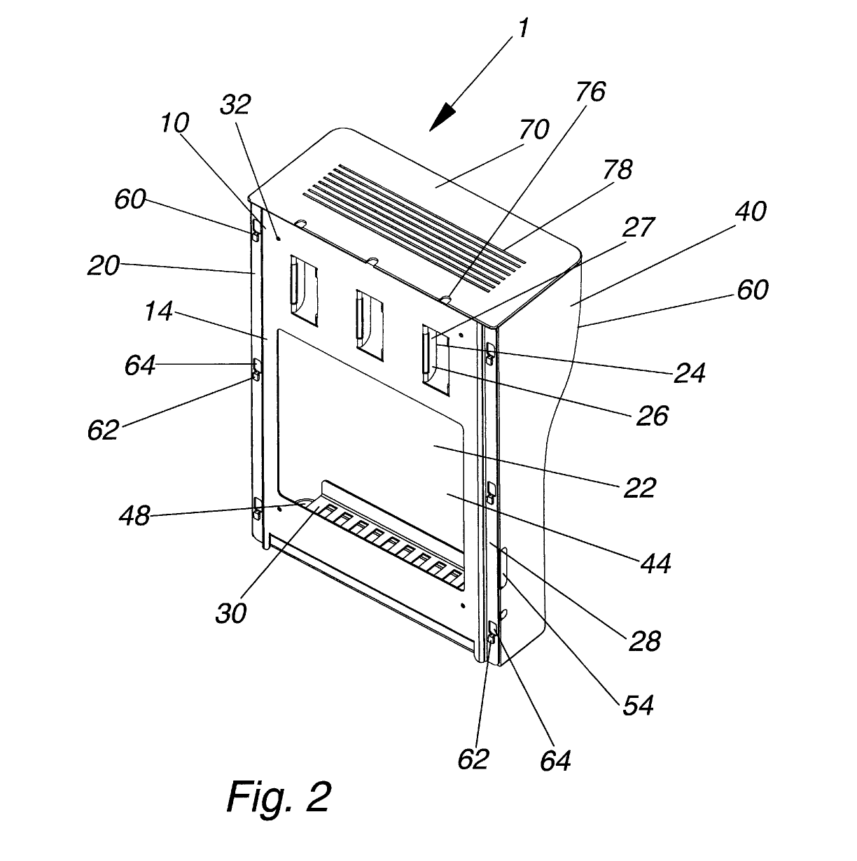

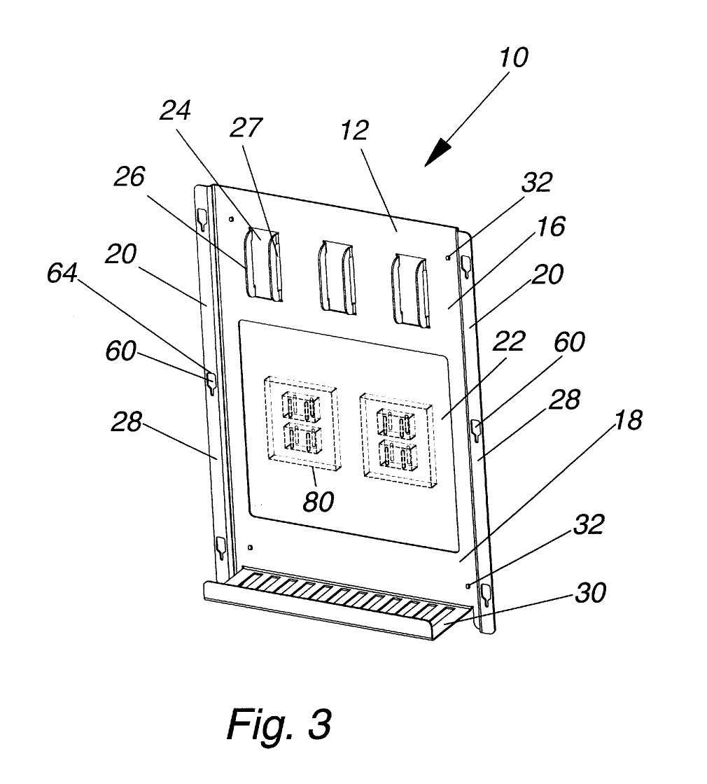

Referring now to FIGS. 1-6, set forth is a cord organizer system 1 comprised of a metal stamped back plate 10, an injection molded, fire retardant cover panel 40 and top cover 70. As shown in FIGS. 2 and 3, the back plate 10 includes a front surface 12, a rear surface 14, an upper edge 16, lower edge 18, and opposing side edges 20. The back plate 10 is securable to a wall with common fasteners 32 such as screws, nails, adhesive, or any other type of fastener that might be beneficial for attachment. For instance, the back plate may be attached to sheet rock with conventional drywall screws. The back plate may be attached to a modular cubicle track system by the use of a male/female fastener, discussed in further detail later. The back plate 10 has a centrally disposed opening 22 for placement around a wall mounted electrical outlet 80. The opening 22 is preferably sized to accommodate all standard two and four electrical plug outlets 80. On the front surface 12, the back plate 10 includes a means for managing electrical cords in an organized manner. A plurality of channels 24 are provided for above the opening 22. The channels 24 are open from front surface 12 to rear surface 14 and have parallel opposing wall slits 26. The wall slits 26 extend outwardly. Along the proximal end (end closest to the front surface) of the wall slit 26 is an opening 27. The openings 27 are provided for the use of plastic clips or zip ties that are secured thereto to further assist in managing electrical cords, not shown. When a cord is directed into the cord organizer, the plastic clips secure the cord to the back plate. The plastic clips are formed from a rigid, yet bendable, plastic so as to maintain the cords in position when routed through the wall slit opening. A shelf 30 is included on the back plate 10 for support of a power strip. The use of a UPS/power strip can be incorporated into the back plate 10. The shelf 30 is sized to match the length and width of a standard power strip and to enable a very short wall cord to be secured to the electrical outlet.

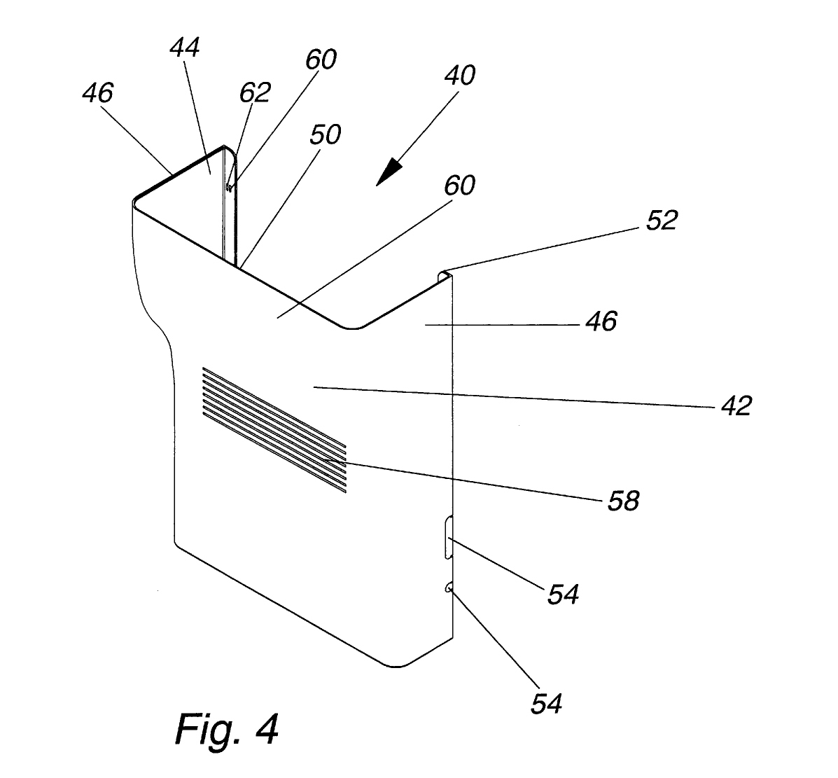

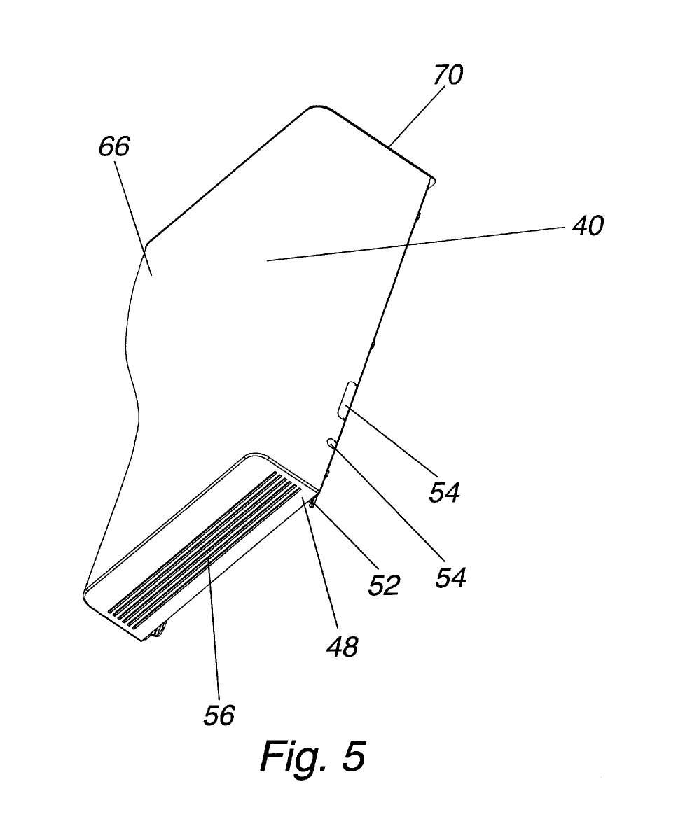

The cover panel 40 is securable to the back plate 10. As shown in FIGS. 4 and 5, the cover panel 40 has a front surface 42, a rear surface 44, opposing side walls 46, a bottom wall 48, and an open top 50. The cover panel 40 is designed to hide and contain electrical cords in a manner that prevents them from interfering with the feet or legs of the operator. All electrical cords that are meant to be organized and plugged into the electrical outlet are preferably fed through the upper protruding portion 66 of the cover panel 40 resulting in sufficient space formed between the cover panel 40 and the back plate 10 to help funnel the electrical cords. The cover panel 40 is preferably formed of a paintable plastic material having slightly rough texture to encourage paint adhesion. The painted surface allows the cover panel 40 to match the wall color and blend in for near invisibility. Side cord openings 54 are placed along at least one side wall 46 of the cover panel 40 for cord entry to accommodate under-counter devices or tower-style computers located on the floor. Although not shown, it is contemplated that the side cord openings will be of an interiorly partially cut-out nature that will allow for easy and clean break-out. The front surface 42 of the cover panel 40 may include a plurality of slats 58 to allow cooler air to be drawn therethrough, thereby creating a chimney effect, cooling the interior of the cord organizer system 1. Vents 56 are also provided for on the bottom wall 48 of the cover panel 40.

The cover panel 40 is secured to the back plate 10 by slidable engagement with overlapping lips, 28 and 52, and a plurality of male/female knob slide fasteners 60, more aptly shown in FIG. 2. Along opposing side edges 20 of the back plate 10 is a lip 28. The lip 28, on each edge mates with a corresponding lip 52 on the cover panel 40 for slidable engagement thereto. The male/female knob slide fastener 60 is defined by female slots 64 on the back plate 10 constructed and arranged to receive the cover panel 40 by use of male knobs 62. As shown, female slots 64 along the lip 28 of the back plate 10 are provided for releasable securement with male knobs 62 on the corresponding lip 52 of the cover panel 40. The use of the male/female knob slide fasteners 60 allows for ease of cover panel 40 removal and access to the back plate 10. It is contemplated that female slots can be provided for on the cover panel and male knobs can be provided for on the back plate.

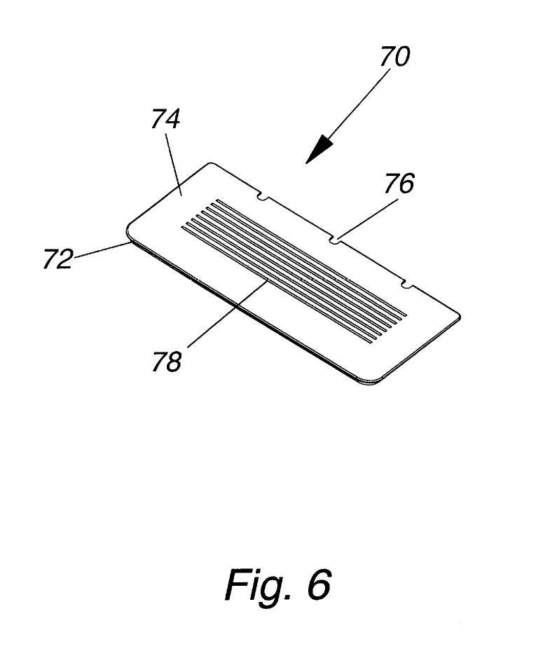

As shown in FIG. 1, a top cover 70 can be placed over the open top 50 of the cover panel 40 and upper edge 16 of the back plate 10 to protect and conceal the contents from debris and further to allow concealment of wires within. Specifically shown in FIG. 6, the top cover 70 includes an edge 72 around the periphery thereof that is sized to contact the open top 50 of the cover panel 40 and upper edge 16 of the back plate 10. Grommet openings 76 on the top surface 72 allow for the routing of cords into the cord organizer system 1 to further allow cord entry from the top yet provide concealment. Ventilation occurs by convection through the use of grills 78 on the top cover 70 and slats 58 and vents 56 on the concealment cover 40. The heated air raises upward and dissipates out the grills 78 on the top cover 70 and cooler air is drawn through the slats 58 and vents 56 on the cover panel 40.

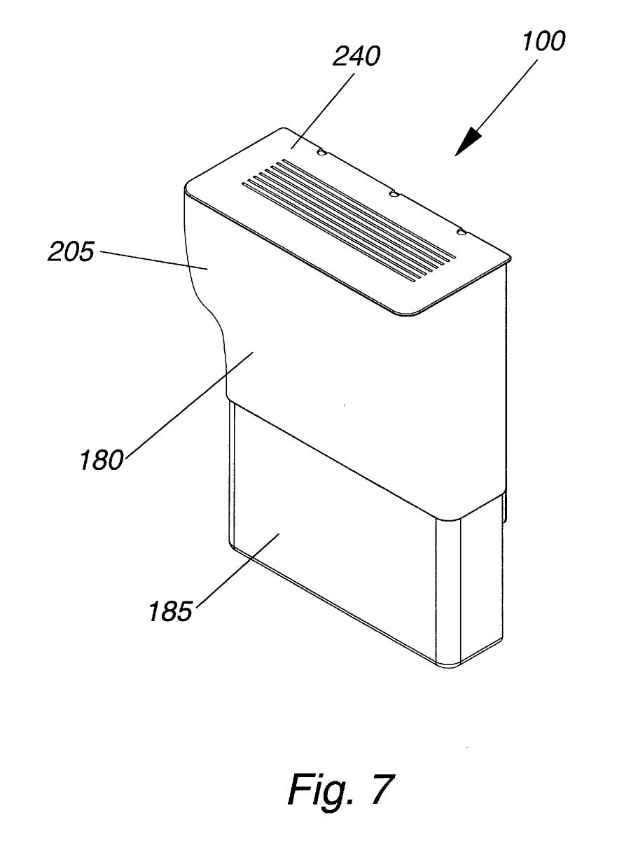

Referring now to FIGS. 7-8 and 14, set forth is a secondary embodiment of the cord organizer system 100. The cord organizer system 100 is comprised of a metal stamped back plate 110, an injection molded, fire retardant cover panel 180 and top cover 240. The back plate 110 is comprised of a top portion 115 and bottom portion back plate 140. The top portion 115 has a front surface 116, rear surface 118, opposing side edges 120, an upper edge 122, and a lower edge 124 having a centrally disposed cut-out 126. The bottom portion 140 has a front surface 142, rear surface 144, opposing side edges 146, a lower portion 148 and an upper edge 150 having a centrally disposed cut-out 152. A plurality of male/female slide fasteners 154 on the opposing side edges, 120 and 146, of the top and bottom portion back plate, 115 and 140, allow for slidable engagement of the top portion back plate 115 and bottom portion back plate 140 and forms a centrally disposed opening 160 for placement over a wall mounted electrical outlet 300, further discussed below. The opening 160 is preferably sized to accommodate all standard two and four electrical plug outlets 300; furthermore the slidable engagement of the top and bottom portion of the back plate, 115 and 140, the opening 160 is adjustable in size. On the front surface 116 of top portion 115 is at least one channel 130 comprised of opposing wall slits 132, above the cut-out 126 for organizing and securing electrical cords to the back plate 110. The channels 130 are open from front surface 116 to rear surface 118 and have opposing wall slits 132. The wall slits 132 extend outwardly. Along the proximal end (end closest to the front surface) of the wall slit 132 is an opening 134. The openings 134 are provided for the use of plastic clips or zip ties that are permanently secured thereto to further assist in managing electrical cords, not shown. When a cord is directed into the cord organizer, the plastic clips secure the cord to the back plate. The plastic clips are formed from a rigid yet bendable plastic so as to maintain the cords in position when routed through the wall slit opening. A shelf 250 is included on the lower portion back plate 140 for support of a power strip. The use of a UPS/power strip can be incorporated into the lower portion back plate 140. The shelf 250 is sized to match the length and width of a standard power strip and use a very short wall cord for securement to the electrical outlet. The top and bottom portion back plate, 115 and 140, are securable to a wall with common fasteners 170 such as screws, nails, adhesive, or any other type of fastener that might be beneficial for attachment. For instance, the back plate may be attached to sheet rock with conventional drywall screws. Additionally, the back plate may be attached to a modular cubicle track system by the use of a male/female fastener, discussed in further detail later.

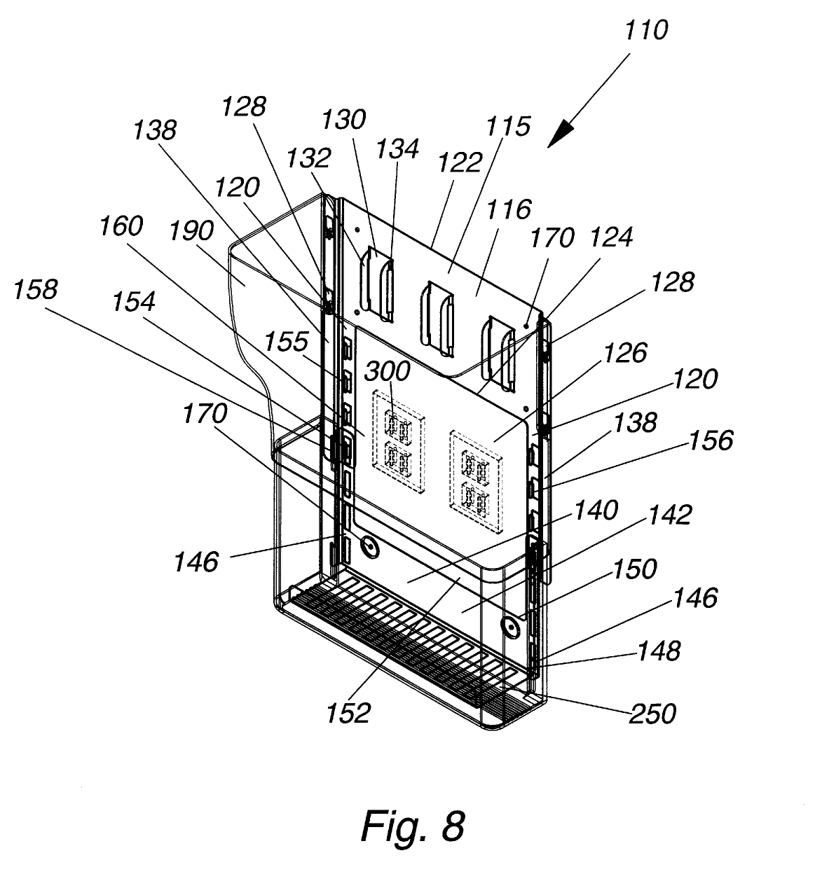

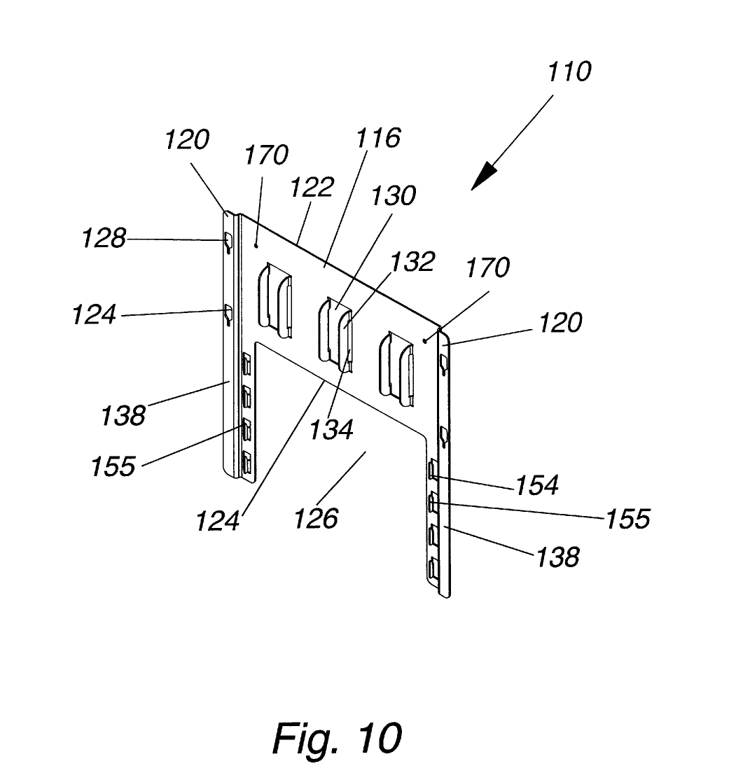

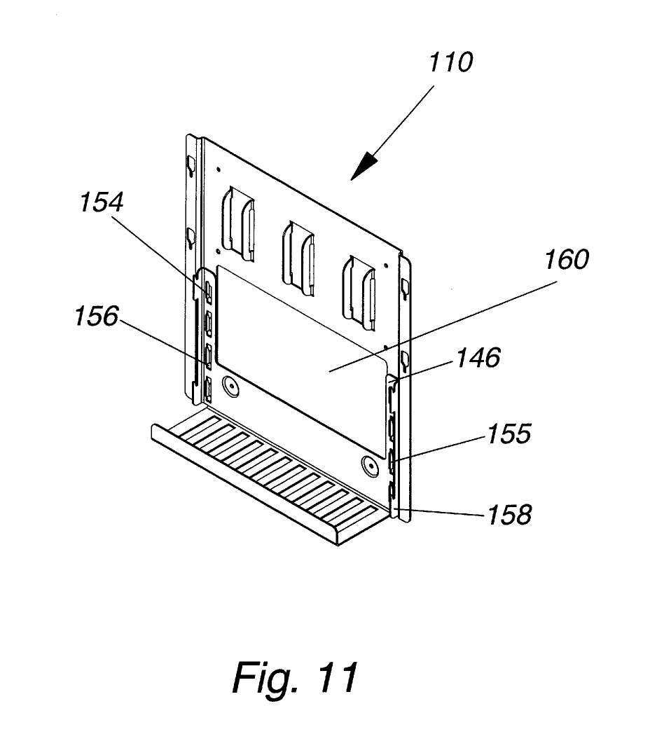

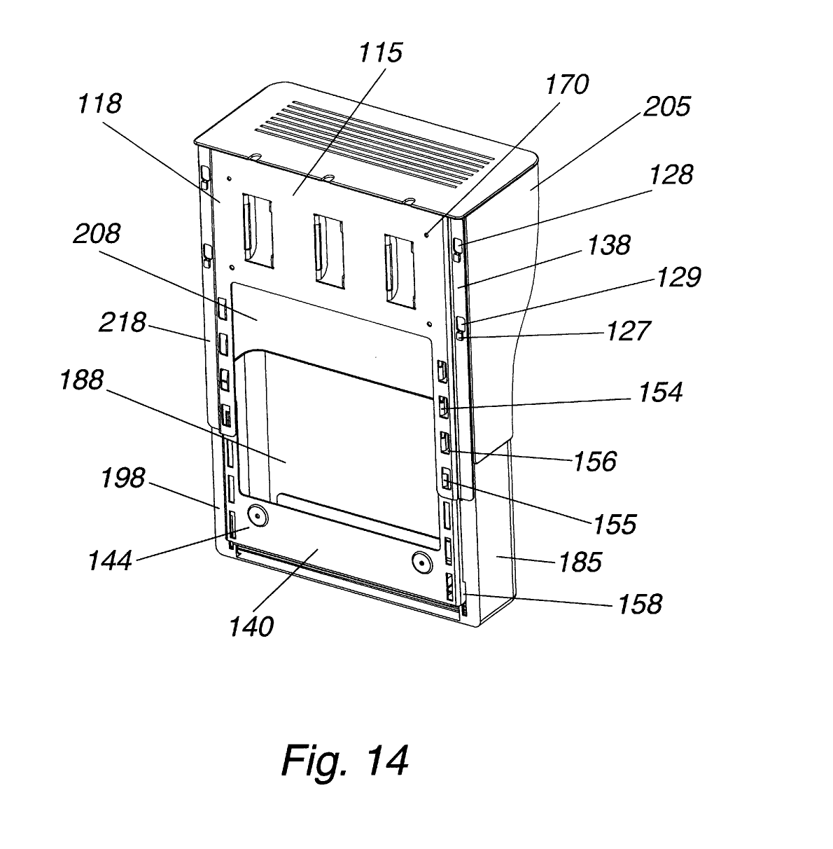

As shown in FIGS. 8, 10-11, and 13-14, along the opposing side edge 120 of the top portion back plate 115 is a lip 138. The lip 138, on each opposing edge 120 mates with a corresponding lip 198 on the upper and lower cover panel, 205 and 185, respectively, for slidable engagement thereto (more aptly shown in FIG. 14). The male/female knob fasteners 128 are comprised of a plurality of female knob slots 129 on each lip 138, the female knob slots 129 are constructed and arranged to receive male knobs 127 on the corresponding lip 218 on the upper portion cover panel 205. Furthermore, the male/female slide hinge fastener 154 is comprised of male slide hinges 155 on the top portion back plate 115 and female openings 156 on the bottom portion back plate 140, shown in FIG. 11, to form a central opening 160 for placement around wall-mounted electrical outlet. Furthermore the slidable engagement of the top and bottom portion of the back plate, 115 and 140, the central opening 160 is adjustable in size. The male slide hinges 155 are disposed between the cut-out opening 126 and the lip 138.

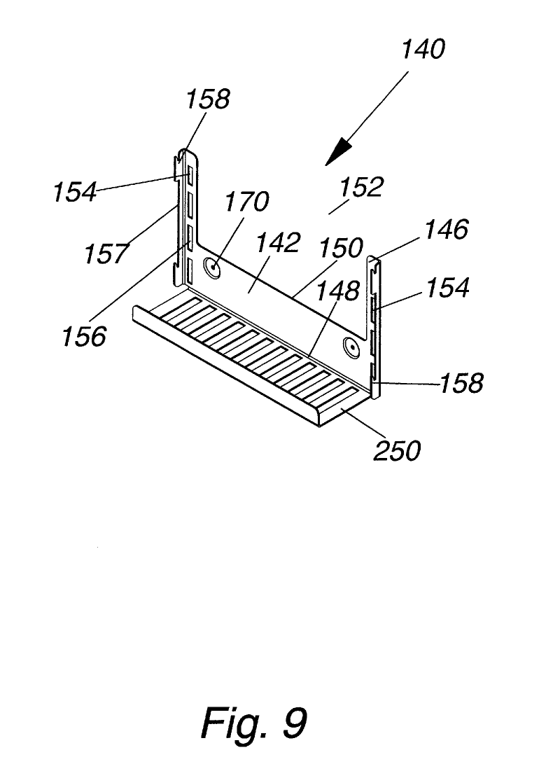

As shown in FIGS. 8, 9, and 11, the opposing side edge 146 on the bottom portion back plate 140 includes at least one outwardly extending hinge 158. The outwardly extending hinge 158 is used for releasable engagement of a corresponding hinge opening 198 on the lower portion cover panel 185, depicted in FIG. 14. The male/female slide fastener 154 is comprised of male slide hinges 155 on the top portion back plate 115 and female openings 156 on the bottom portion back plate 140. The female openings 156 are disposed between the cut-out opening 152 and the edge 146 on the lower portion back plate 140. The female openings 156 are constructed to mate with the male hinges 155 on the top portion back plate 115 to form a central opening 160 for placement around wall-mounted electrical outlet 240. The size of the centrally disposed opening 160 is dependent upon where the female opening 156 on the bottom portion back plate 140 is mated with the male hinge 155 on the top portion back plate 115.

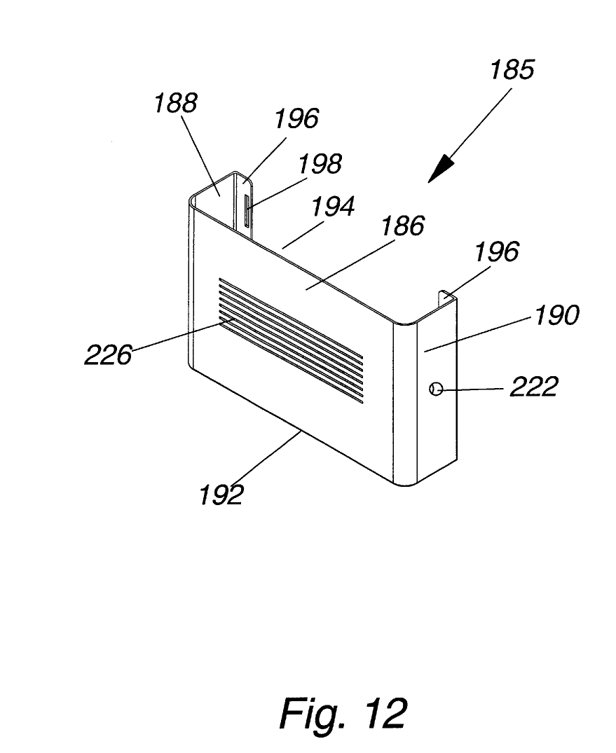

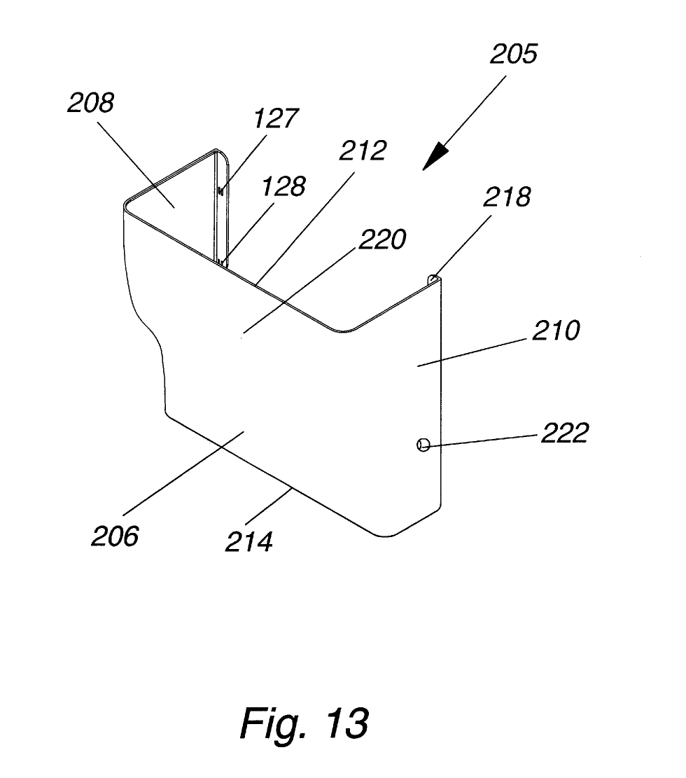

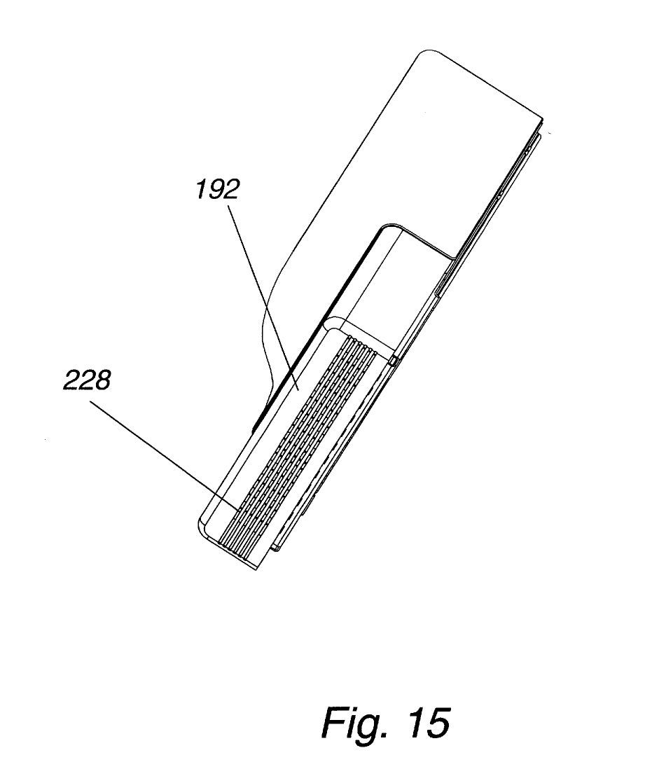

As shown in FIGS. 12-15, the cover panel is comprised of a lower portion 185 and upper portion cover panel 205. The lower portion cover panel 185 has a front surface 186, rear surface 188, opposing side walls 190, a bottom wall 192, and an open top 194. The upper portion cover panel 205 has a front surface 206, rear surface 208, opposing side walls 210, an open top 212, and a bottom edge 214 constructed and arranged to overlap at least a portion of the open top 194 of the lower portion cover panel 185. The cover panel 180 is preferably formed of a paintable plastic material having slightly rough texture to encourage paint adhesion. The painted surface allows the cover panels, 185 and 205, to match the wall color and blend in for near invisibility. Cord openings 222 are placed along at least one side wall 190 of the lower portion cover panel 185 for cord entry to accommodate under-counter devices or tower-style computers that are placed on the floor. However, it is contemplated that the cord opening can be placed along the side wall of the upper cover panel, shown in FIG. 13. Furthermore, the cover panels, 185 and 205, may include a plurality of slats 226 extending from the front surface 186 to the rear surface 188 to allow air to circulate within cord organizer on the lower portion cover panel 185 or the upper portion cover panel 205, not shown. The bottom wall 192 of the lower portion cover panel 185 includes a plurality of vents 228. The slats 226 and vents 228 help dissipate heat within the cord organizer 100 by convection, further discussed later.

The cover panel 180, comprised of lower portion 185 and upper portion cover panel 205, is secured to the back plate 110, comprised of top portion 115 and bottom portion back plate 140, by slidable engagement with overlapping lips (lips on the top portion back plate 138 with corresponding lips 196 and 218 on the lower and upper portion cover panel) and a plurality of male/female knob slide fasteners 128, more aptly shown in FIG. 14. Referring to FIG. 8, along opposing side edges 120 of the top portion back plate 115 is a lip 138. The lip 138, on each opposing edge 120 mates with a corresponding lip, 196 and 218, on the lower 185 and upper cover panel 205, respectively, for slidable engagement thereto. The male/female knob slide fastener 128 is defined by female slots 129 on the top portion back plate 185 that are constructed and arranged to receive the upper cover panel 205 by use of male knobs 127. As shown in FIG. 14, female slots 129 along the lip 138 of the top portion back plate 115 are provided for releasable securement with male knobs 127 on the corresponding lip 218 of the upper portion cover panel 205. The use of the male/female knob slide 128 allows for ease of removal of cover panel 180 and access to the back plate 110. It is contemplated that female slots may be provided for on the cover panel and male knobs are provided for on the back plate. Additionally, the opposing side edge 146 on the bottom portion back plate 140 includes at least one outwardly extending hinge 158, and the opposing side walls 190 on the lower portion cover panel 185 includes at least one corresponding hinge opening 198 for releasable engagement of the bottom portion back plate 140 to lower portion cover panel 185, shown in FIG. 14.

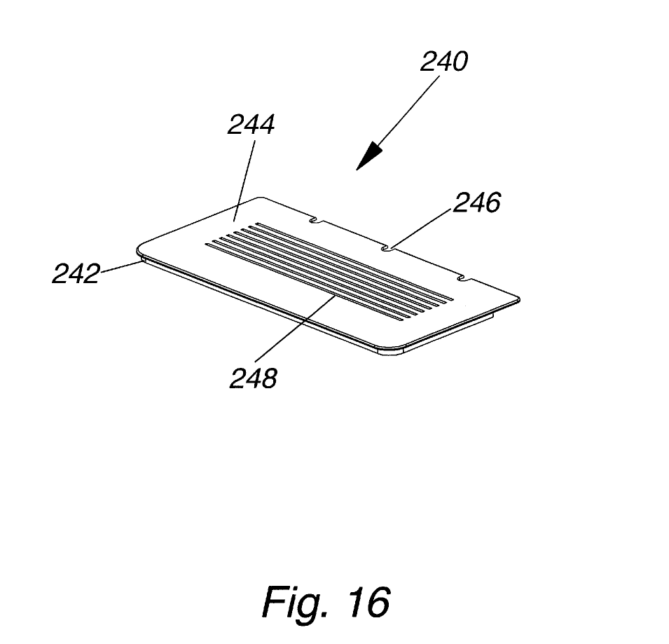

As shown in FIGS. 7 and 16, a top cover 240 is constructed and arranged to circumscribe the open top 212 on the upper cover panel 205 and upper edge 122 on top portion back plate 115 to conceal the contents from debris and further to allow concealment of wires within. Specifically, the top cover 240 includes an edge 242 around the periphery thereof that is sized to contact the open top 212 on the upper cover panel 205 and upper edge 122 on top portion back plate 115. The top cover 240 includes at least one grommet opening 246 on the top surface 244 to allow for the entry of electrical cords. The grommet openings 246 on the top cover 240 allow for the routing of cords into the cord organizer system 100 to further allow cord entry from the top yet provide concealment. Ventilation occurs by convection through the use of grills 248 on the top cover 240 and slats 226 and vents 228 on the concealment cover 180. The heated air raises upward and dissipates out the grills 248 on the top cover 240 and cooler air is drawn through the slats 226 and vent 228 on the cover panel 180.

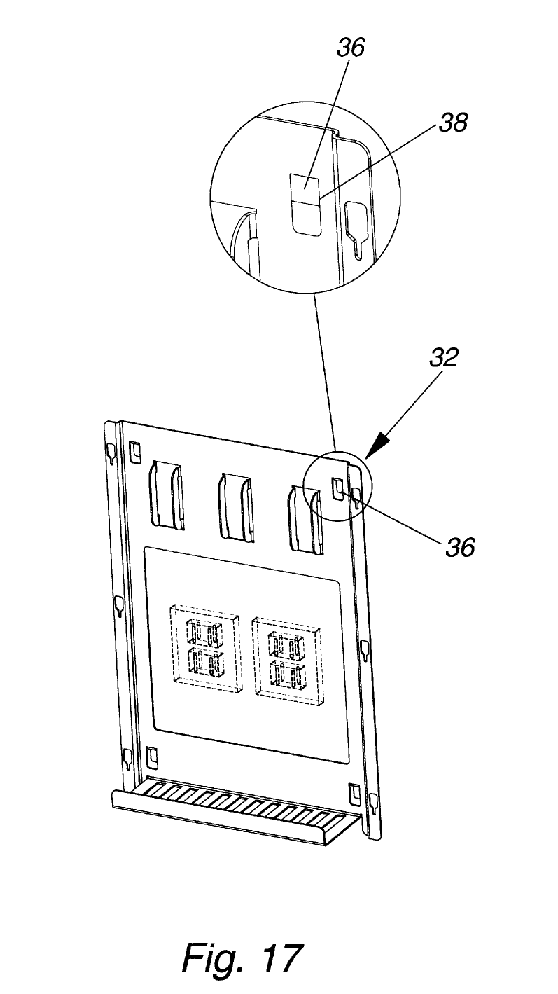

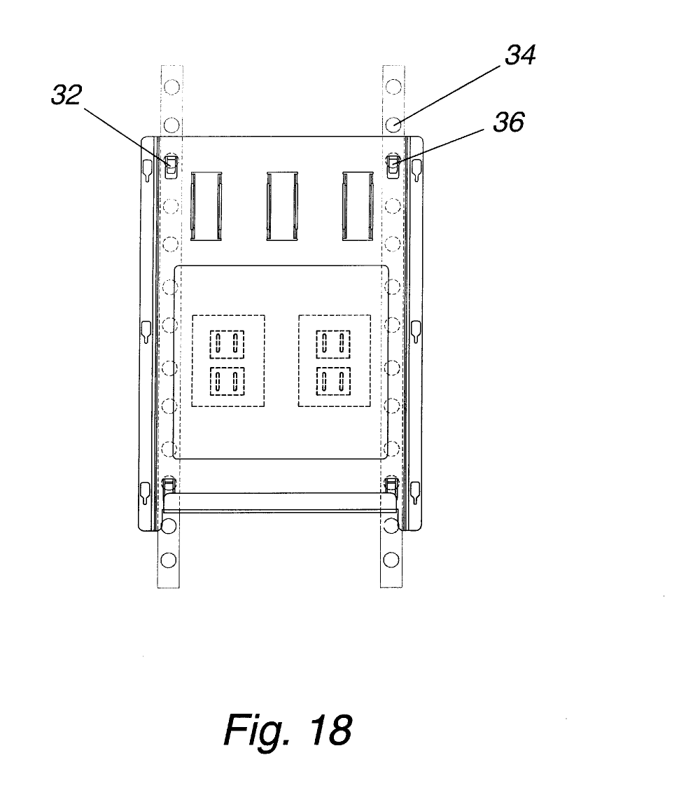

In an alternative embodiment, shown in FIGS. 17 and 18, the cord organizer system can include a hanger-style attachment fastener 32 to attach the back plate 10 to a tracking system on a cubicle or desk. A plurality of fasteners 32 at an intermittent spacing and width will be provided so that the cord organizer is adaptable to a multitude of tracking systems produced by various manufactures. Specifically, the back plate includes a plurality of male hooks 36 along the opposing side edges. The plurality of male hooks 36 is equally spaced apart for engaging compatible female slots 34 on an office desk tracking. The plurality of male hooks 36 is formed by a partially perforated portion 38 of the back plate side edges, wherein the partially perforated portion 38 is bendable. The user can bend the perforated portion 38 backwards to form a male hook 36. It is contemplated that the back plate may include female slots for engaging male hooks on a track, not shown. It is also contemplated that any means for fastening the back plate to a track used by various manufacturers can be implemented into the back plate, not shown.

Detailed embodiments of the instant invention are disclosed herein, however, it is to be understood that the disclosed embodiments are merely exemplary of the invention, which may be embodied in various forms. Therefore, specific functional and structural details disclosed herein are not to be interpreted as limiting, but merely as a basis for the claims and as a representation basis for teaching one skilled in the art to variously employ the present invention in virtually any appropriately detailed structure.

All patents and publications mentioned in this specification are indicative of the levels of those skilled in the art to which the invention pertains. All patents and publications are herein incorporated by reference to the same extent as if each individual publication was specifically and individually indicated to be incorporated by reference. It is to be understood that while a certain form of the invention is illustrated, it is not to be limited to the specific form or arrangement herein described and shown. It will be apparent to those skilled in the art that various changes may be made without departing from the scope of the invention and the invention is not to be considered limited to what is shown and described in the specification and any drawings/figures included herein.

One skilled in the art will readily appreciate that the present invention is well adapted to carry out the objectives and obtain the ends and advantages mentioned, as well as those inherent therein. The embodiments, methods, procedures and techniques described herein are presently representative of the preferred embodiments, are intended to be exemplary and are not intended as limitations on the scope. Changes therein and other uses will occur to those skilled in the art which are encompassed within the spirit of the invention and are defined by the scope of the appended claims. Although the invention has been described in connection with specific preferred embodiments, it should be understood that the invention as claimed should not be unduly limited to such specific embodiments. Indeed, various modifications of the described modes for carrying out the invention which are obvious to those skilled in the art are intended to be within the scope of the following claims.

What is claimed is:

1. A cord organizer system comprising:
a back plate having a front surface, a rear surface, an upper edge, lower edge, and opposing side edges, said back plate having a centrally disposed opening for placement over a wall mounted electrical outlet;
at least one channel section having opposing wall slits formed into said front surface of said back plate above said centrally disposed opening; and
a cover panel releasably securable to said back plate, said cover panel having a front surface, a rear surface, opposing side walls, a bottom wall and an open top, wherein said channel section permits organizing and securing of electrical cords plugged into the electrical outlet whereby said cover panel conceals said electrical cords from view.

2. The cord organizer according to claim 1, including a male/female knob slide for securement of said cover panel to said back plate.

3. The cord organizer according to claim 1, wherein said opposing side edges on said back plate includes a lip constructed and arranged to engage a corresponding lip on said cover panel for releasable slidable engagement of said panel to said back plate.

4. The cord organizer according to claim 1, wherein said channel section supports an electrical cord.

5. The cord organizer according to claim 1, wherein said back plate includes a shelf for support of an electrical plug power strip.

6. The cord organizer according to claim 5, wherein said opposing side walls on said cover panel extends beyond said shelf for concealment of cords.

7. The cord organizer according to claim 1, wherein said back plate is secured to a wall by use of a fastener selected from the group comprising screws, nails, adhesive, hook and loop.

8. The cord organizer according to claim 1, wherein said back plate includes a plurality of hanger-style male fasteners along opposing side edges.

9. The cord organizer according to claim 8, wherein said plurality of hanger-style male fasteners is equally spaced apart for engaging compatible female slots on an office desk tracking.

10. The cord organizer according to claim 9, wherein said plurality of hanger-style male fasteners is formed by a partially perforated bendable portion of said side edges.

11. The cord organizer according to claim 1, wherein said cover panel includes a plurality of slats extending from said front surface to said rear surface to allow air to circulate within said cord organizer.

12. The cord organizer according to claim 1, wherein a top cover is constructed and arranged to circumscribe said open top on said cover panel and said upper edge on said back plate, wherein said top cover includes at least one opening to allow for the entry of electrical cords.

13. The cord organizer according to claim 1, wherein said cover panel is textured.

14. The cord organizer according to claim 13, wherein said cover panel is paintable.

15. A cord organizer system comprising:
a back plate comprising of:
a top portion back plate having a front surface, rear surface, opposing side edges, an upper edge, and a lower edge having a centrally disposed cut-out;
a bottom portion back plate having a front surface, rear surface, opposing side edges, a lower edge and an upper edge having a centrally disposed cut-out;
a plurality of male/female slide hinge fasteners on said opposing side edges of said top and bottom portion back plate, whereby slidable engagement of said top and bottom portion back plate forms an adjustably sized centrally disposed opening from placement over a wall mounted electrical outlet;
at least one channel comprising of opposing wall slits formed into said front surface, above said cut-out, of said top portion back plate for organizing and securing electrical cords to said back plate; and
a cover panel comprising of:
a lower portion cover panel having a front surface, rear surface, opposing side walls, a bottom wall, and an open top;
an upper portion cover panel having a front surface, rear surface, opposing side walls, an open top, and a bottom edge constructed and arranged to overlap at least said open top of said lower portion cover panel and securable thereto;
wherein said cover panel being releasably secured to said back plate.

16. The cord organizer according to claim 15, wherein said opposing edges on said top portion back plate has a lip, and said opposing side walls on said top and bottom cover panel has a corresponding lip for slidable engagement of said top portion back plate to said cover panel.

17. The cord organizer according to claim 15, wherein a male/female knob slide on said opposing edge of said top portion back plate and said upper portion cover panel is used for releasable securement thereof.

18. The cord organizer according to claim 15, wherein said opposing side edge on said bottom portion back plate includes at least one outwardly extending hinge, and said opposing side walls on said lower portion cover panel includes at least one corresponding hinge for releasable engage of said bottom portion back plate to said lower portion cover panel.

19. The cord organizer according to claim 15, wherein said opposing side walls on said cover panel includes at least one cut-out opening for entry of electrical cords.

20. The cord organizer according to claim 15, wherein said bottom portion back plate includes a shelf for support of a power strip.

21. The cord organizer according to claim 15, wherein said back plate is secured to a wall by use of a fastener.

22. The cord organizer according to claim 15, wherein said back plate includes a plurality of hanger-style male fasteners along opposing side edges.

23. The cord organizer according to claim 22, wherein aid plurality of hanger-style male fasteners is equally spaced apart for engaging compatible female slots on an office desk tracking.

24. The cord organizer according to claim 23, wherein said plurality of hanger-style male fasteners is formed by a partially perforated portion of said side edges, wherein said partially perforated portion is bendable.

25. The cord organizer according to claim 15, wherein said cover panel includes a plurality of slats extending from said front surface to said rear surface to allow air to circulate within said cord organizer.

26. The cord organizer according to claim 15, wherein a top cover is constructed and arranged to circumscribe said open top on said upper portion cover panel and said upper edge on said top portion back plate, wherein said top cover includes at least one opening to allow for the entry of electrical cords.

27. The cord organizer according to claim 15, wherein said front surface of said cover panel is constructed from a paintable material.
